(19) United States
(12) Patent Application Publication
(10) Pub. No.: US 2025/0232941 A1
(43) Pub. Date: Jul. 17, 2025

(54) WAFER EDGE INSPECTION OF CHARGED PARTICLE INSPECTION SYSTEM

(71) Applicant: ASML Netherlands B.V., Veldhoven (NL)

(72) Inventors: Zizhou GONG, San Jose, CA (US); Xiaoyu JI, San Jose, CA (US); Oleg KRUPIN, San Jose, CA (US); Weiming REN, San Jose, CA (US)

(73) Assignee: ASML Netherlands B.V., Veldhoven (NL)

(21) Appl. No.: 18/854,000

(22) PCT Filed: Mar. 13, 2023
(86) PCT No.: PCT/EP2023/056302

§ 371 Date: Oct. 3, 2024

Related U.S. Application Data
(60) Provisional application No. 63/330,249, filed on Apr. 12, 2022.

(51) Int. Cl. H01J 37/02; H01J 37/20

(52) U.S. Cl. CPC H01J 37/026; H01J 37/20; H01J 2237/0262; H01J 2237/2812

(57) ABSTRACT

An improved system is disclosed for wafer outer portion inspection in a charged particle beam system, such as a scanning electron microscope (SEM). The system uses multiple conductive rings around the wafer to correct an e-field distortion occurring at the wafer outer portion. The rings are applied with different complimentary voltages in order achieve a precise compensation of the e-field distortion.

### CROSS-REFERENCE TO RELATED APPLICATIONS

This application claims priority of U.S. application 63/330,249 which was filed on 12 Apr. 2022 and which is incorporated herein in its entirety by reference.

### FIELD

The description herein relates to the field of charged particle beam apparatus, and more particularly to wafer edge inspection for a charged particle inspection system.

### BACKGROUND

A charged particle beam apparatus is able to produce a 2-dimensional image of a wafer substrate by detecting secondary electrons, backscattered electrons, mirror electrons, or other kinds of electrons from the surface of the wafer substrate upon impingement by a charged particle beam generated by the charged particle beam apparatus. Various charged particle beam apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), defect analysis (e.g., defect review SEM, or say DR-SEM and Focused Ion Beam system, or say FIB), etc.

During wafer inspection, any potential defects in the wafer can be discovered and removed so that flawless structures may be formed in the wafer at a later stage. During the wafer inspection process, the wafer can be placed inside of a conductive ring, also referred to as a high voltage (HV) ring structure on a wafer holder (stage). The conductive ring may also be referred to as a compensation ring. A compensation voltage is usually applied on this conductive ring to further reduce distortion of the electric field near the outer portion of a wafer, and thereby reducing misalignment and resolution degradation of the scanned image in this area. However, even with such compensation, the misalignment and resolution degradation still cannot be reduced sufficiently.

### SUMMARY

Embodiments of the present disclosure provide systems and methods for inspecting the edge of a sample in a charged particle beam system.

Some embodiments provide a system for reducing e-field distortion near an outer portion of a wafer comprising: a wafer holder comprising a holding portion configured to hold a wafer, the wafer having a first outer diameter; a first conductive electrode configured to surround the wafer, the first conductive electrode having a second inner diameter and a third outer diameter, the second inner diameter being larger than the first outer diameter; a second conductive electrode configured to encircle the first conductive electrode, the second conductive ring having a fourth inner diameter larger than the second inner diameter; a first, second, and third voltage supply, the first voltage supply being connected to the first conductive electrode, the second voltage supply being connected to the second conductive electrode, the third voltage supply being connected to the wafer; and a controller configured to control each of the first, second, and third voltage supplies to operate at a first, second, and third voltage respectively; wherein the first, second and third voltages are selected to reduce distortion of an e-field at the outer portion of the wafer, and the first, second and third voltages are different from each other.

Some embodiments provide a non-transitory computer-readable medium storing a set of instructions that are executable by at least one processor of a device to cause the device to perform a method comprising: loading a wafer onto a wafer holder comprising a holding portion, the wafer having a first outer diameter; applying a first voltage to a first conductive electrode encircling the holding portion, the first conductive electrode having a second inner diameter and a third outer diameter, the second inner diameter being larger than the first outer diameter; applying a second voltage to a second conductive electrode encircling the first conductive electrode, the second conductive electrode having a fourth inner diameter larger than the second inner diameter; and applying a third voltage to the wafer; wherein the first, second and third voltages are selected to reduce distortion of an e-field at the outer portion of the wafer, and the first, second and third voltages are different from each other.

Further objects and advantages of the disclosed embodiments will be set forth in part in the following description, and in part will be apparent from the description, or may be learned by practice of the embodiments. Some objects and advantages of the disclosed embodiments may be realized and attained by the elements and combinations set forth in the claims. However, embodiments of the present disclosure are not necessarily required to achieve such exemplary objects or advantages, and some embodiments may not achieve any of the stated objects or advantages.

It is to be understood that both the foregoing general description and the following detailed description are exemplary and explanatory only and are not restrictive of the disclosed embodiments. as may be claimed.

### BRIEF DESCRIPTION OF THE DRAWINGS

FIG. 1 is a schematic diagram illustrating an example electron beam inspection (EBI) system, consistent with some embodiments of the present disclosure.

FIG. 2 is a schematic diagram illustrating an example electron beam tool, consistent with some embodiments of the present disclosure that may be a part of the example electron beam inspection system of FIG. 1.

FIG. 3 is an illustration of a top view of an example system according to a comparative embodiment.

FIG. 4 is an illustration of a cross-sectional view of the example system of FIG. 3, according to a comparative embodiment.

FIG. 5 is an illustration of a cross-sectional view of an example system according to a comparative embodiment.

FIG. 6 is an illustration of a cross-sectional view of the example system of FIG. 5, according to a comparative embodiment.

FIG. 7A is an illustration of a top view of an example multi-ring system, consistent with some embodiments of the present disclosure.

FIG. 7B is an illustration of a cross-sectional view of an example multi-ring system, consistent with some embodiments of the present disclosure.

FIGS. 8A-8D are illustrations of example configurations applying various voltages to a multi-ring system, consistent with some embodiments of the present disclosure.

FIGS. 9A-9C are illustrations of example configurations using coatings on an insulating block of a ring system, consistent with some embodiments of the present disclosure.

FIG. 10A is an illustration of a top view of an example system during wafer loading, consistent with some embodiments of the present disclosure.

FIG. 10B an illustration of a top view of the example system of FIG. 10A after wafer loading. consistent with some embodiments of the present disclosure.

FIG. 11 shows an example comparison between a single conductive ring of a comparative embodiment and a multi-ring system according to embodiments of the present disclosure.

FIG. 12 illustrates a flowchart of an example method for compensating edge field distortion in a charged particle beam process, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example. an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures.” resulting in more electrons exiting from the structures. Accordingly, the detector may receive more exiting electrons simultaneously and generate inspection images of the structures of the wafer with higher efficiency and faster speed.

Typically, the structures are made on a substrate (e.g., a silicon substrate) that is placed on a platform, referred to as a stage or an electric chuck (e-chuck), for imaging. The platform can include a wafer holder that surrounds the wafer. In conventional wafer platform systems, when the wafer is placed in the wafer holder, there is a gap between the wafer edge and an inner circle of the wafer holder. This gap creates a discontinuity or distortion of an e-field at an outer portion of the wafer including the wafer edge, which impacts the performance of the SEM. In particular, the distortion of the e-field can cause an electron beam to defocus, deflect, or distort, thereby impacting any corresponding image of the wafer. In some instances, a high-voltage (HV) ring structure located near to the gap can be used to supply an additional voltage so that the electric potential at the outer portion of the wafer is more uniform. A outer portion of a wafer may be considered a peripheral region of the wafer that is within a predetermined distance of the wafer edge. In some embodiments of the present disclosure, an outer portion may be a peripheral region of a wafer that is within 1 mm, 2 mm, 3 mm, 5 mm, 10 mm or 20 mm of a wafer edge. However, the conductive ring may be fixed and the gap between the wafer edge and the ring may not be adjustable Problems can occur when the wafer is not situated perfectly within the ring structure, such as situations when the wafer is off center. In such situations, the conductive ring may need to provide different compensation voltages at different locations. Moreover, in at least some conventional systems, the conductive ring may be below the wafer surface, thereby requiring a very high compensation voltage (several kV) to obtain a desired compensation performance.

To overcome the issues discussed above, a ring may be positioned so as to be planar with the wafer upper surface and contact, or come as near as possible to, the wafer edge. This may make the electric potential distribution near the wafer outer portion more uniform. However, some wafer edge contours may prevent the segments from perfectly abutting the wafer. For example, a chamfered edge, alignment notch, or manufacturing imperfection may cause a residual gap between the ring and the wafer.

In general, in current conventional systems, the distorted e-field cannot be fully compensated or additional compensation elements in the electron optics system may need to be adjusted to reduce the impact on image quality to an acceptable level. Thus, current systems and processes of wafer inspection can result in many errors due to a non-uniform e-field near the wafer outer portion.

To improve the wafer inspection process, it may be advantageous to eliminate or minimize e-field distortion at the wafer outer portion. According to at least some embodiments of the present disclosure, a multi-ring system is proposed. The arrangement may comprise a first ring surrounding the wafer, and a second ring surrounding the first ring. The first and second rings may therefore be called an inner ring and outer ring, respectively. The system may include a first and second voltage supply configured to supply different first and second voltages to the inner and outer rings. The system may include a third voltage supply configured to supply a third voltage to the wafer, the third voltage being different from the first or second voltages. The combined voltages may result in a more uniform e-field at an outer portion of the wafer. The inner or outer rings may be adjustable segmented electrically conductive rings. The inner or outer rings may be embodied as conductive films on a piece of mirror block on the wafer holder.

As used herein, unless specifically stated otherwise, the term “or” encompasses all possible combinations, except where infeasible. For example, if it is stated that a component may include A or B. then, unless specifically stated otherwise or infeasible, the component may include A, or B, or A and B. As a second example, if it is stated that a component may include A, B, or C, then, unless specifically stated otherwise or infeasible, the component may include A, or B. or C, or A and B, or A and C, or B and C, or A and B and C.

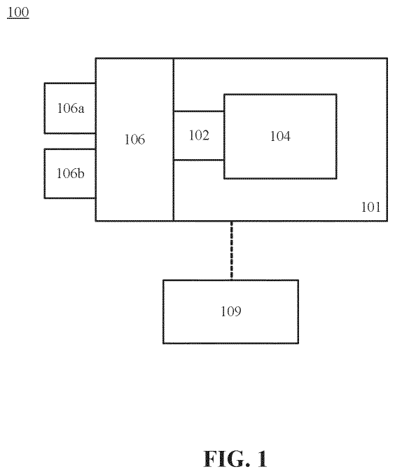

FIG. 1 illustrates an exemplary electron beam inspection (EBI) system 100 consistent with some embodiments of the present disclosure. EBI system 100 may be used for imaging. As shown in FIG. 1. EBI system 100 includes a main chamber 101, a load/lock chamber 102, a beam tool 104, and an equipment front end module (EFEM) 106. Beam tool 104 is located within main chamber 101.

EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller-109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

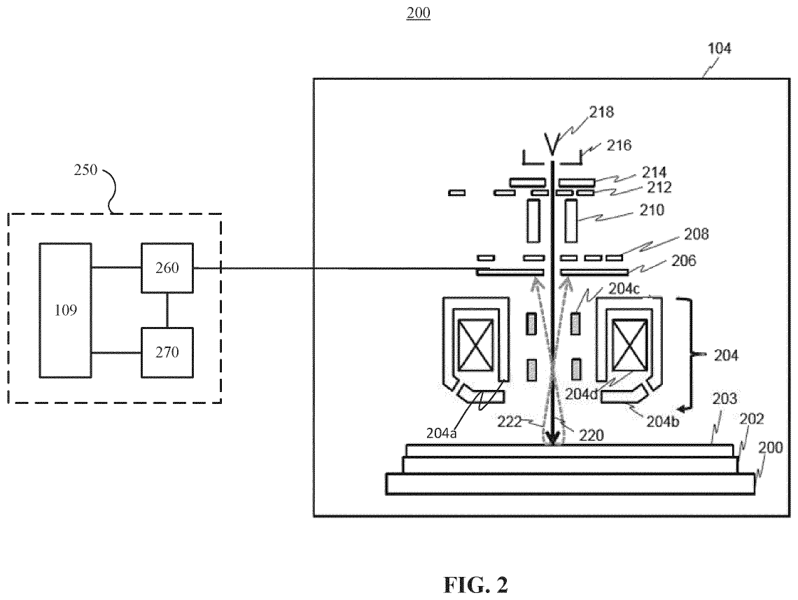

FIG. 2 illustrates an example imaging system 200 according to embodiments of the present disclosure. Electron beam tool 104 of FIG. 2 may be configured for use in EBI system 100 of FIG. 1. Electron beam tool 104 may be a single beam apparatus or a multi-beam apparatus. As shown in FIG.

2, electron beam tool 104 includes a motorized sample stage 201, and a wafer holder 202 supported by motorized sample stage 201 to hold a wafer 203 to be inspected. The wafer holder comprises a holding portion configured to hold the wafer by, e.g., electrostatic attraction. Electron beam tool 104 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective aperture 208 or beam limit aperture 212 may be, e.g., an array of apertures. It is appreciated that the electron detector 206 can also be a single piece, e.g., an annular type. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an Energy Dispersive X-ray Spectrometer (EDS) detector (not shown) to characterize the materials on wafer 203.

A primary electron beam 220 is emitted from cathode 218 by applying an acceleration voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 at different incidence angles onto different sides of a feature of wafer 203 at a particular location, at different time points. This may be used to provide data for stereo image reconstruction of the wafer structure at that location.

Further, in some embodiments, anode 216 and cathode 218 may generate multiple primary electron beams 220 using, e.g., a source conversion unit (not shown). A source-conversion unit may change a single electron source into a virtual multi-source array. Electron beam tool 104 may further include a plurality of deflectors 204c to scan the multiple primary electron beams 220 onto the wafer at the same time, to provide data for image reconstruction for different parts of wafer 203. Further details of source conversion units may be found in U.S. Pat. No. 9,691,588, the entirety of which is incorporated herein by reference.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an e-field. The e-field reduces the energy of impinging primary electron beam 220 near the surface of wafer 203 before it collides with wafer 203. Control electrode 204b, being electrically isolated from pole piece 204a, controls an e-field on wafer 203 to prevent micro-arcing of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, or the like.) that represents an intensity of the beam spot and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer, or at different incidence angles onto the wafer at a particular location, to generate secondary electron beam 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes an electron beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of electron beam tool 104 through a medium such as an electrical-conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

In some embodiments, information from image acquirer may be used to characterize distortion of the e-field. For example, an image may include a characteristic type of image distortion that corresponds to an expected type of e-field distortion at the wafer outer portion. The image may also be compared to a reference feature layout at the wafer outer portion in order to identify distortion.

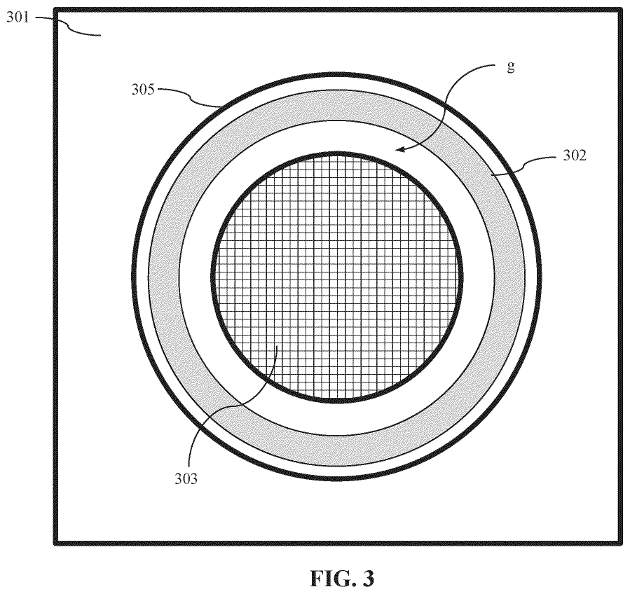

FIG. 3 illustrates a top view of an example wafer system according to a comparative embodiment. A system for compensating distortion at an outer portion of a wafer 303 comprises a compensating electrode 302 between wafer 303 and an inner side 305 of wafer holder 301. separated from wafer 303 by a gap g. Compensating electrode 302 is separated from wafer 303 by a gap g. A voltage is applied to compensating electrode in order to offset a distortion in the electric potential distribution at an outer portion of wafer 303.

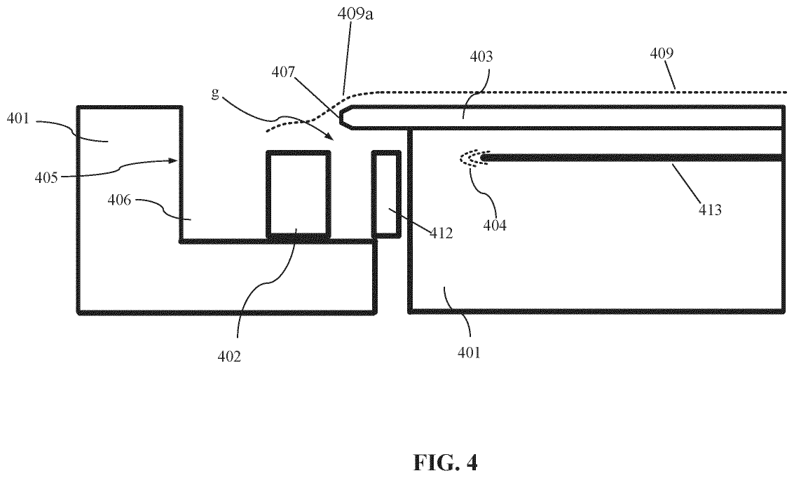

FIG. 4 comprises illustrates a cross-sectional view of the system of FIG. 3. Here, compensating electrode 402 is located entirely below the level of wafer 403. This placement requires a very high compensating voltage of, e.g., several kV. Even with a high voltage, because there is only one electrode, the distribution of electric potential does not take an ideal form for compensating distortions of an outer portion of wafer 403. As a result, an electric potential distribution 409 in a region over wafer 403 exhibits distortion 409a at an outer portion of wafer 403. The distortion extends past wafer edge 407.

Some comparative embodiments may include a further electrode 412 that is positioned inward of a wafer edge 407 and below the underside of wafer 403. This type of further electrode 412 is not configured for acting on distortion at a wafer outer portion, but instead is configured as a screening electrode to shield electric field 404 of chucking electrode 413. Because of its location and because the applied voltage is selected for a different purpose, screening electrode 412 cannot cooperate with compensating electrode 402 to sufficiently reduce e-field distortion 409a at an outer portion of wafer 403.

In some comparative embodiments, an upper surface of electrode 402 is located above wafer 403, but the e-field compensation would still be suboptimal for the reasons just described. Because there is only one electrode, there is a large shape mismatch between a wafer outer portion field and a compensation field. Thus, the single-ring system of FIGS. 3-4 would require SEM column adjustments at each location on a wafer outer portion in order to bring a beam shift and spot size within specifications. This process is very time-consuming and harms inspection throughput.

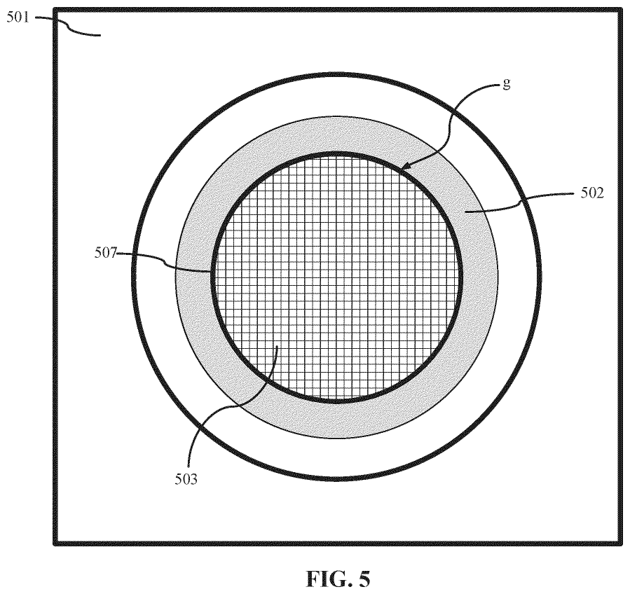

FIG. 5 illustrates a top view of a wafer system according to another comparative embodiment. Here a compensation ring 502 is designed to abut an edge of wafer 503 and be substantially coplanar with its upper surface. Under this comparative embodiment, the voltages applied to compensation ring 502 and wafer 503 are ideally substantially equal.

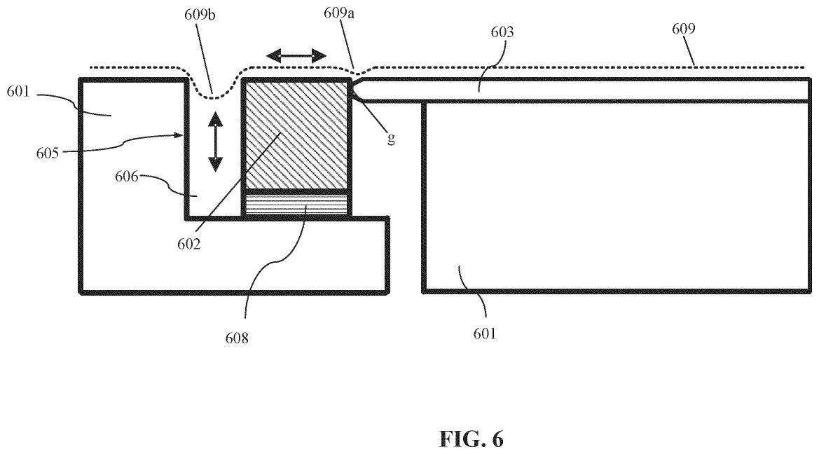

FIG. 6 illustrates a cross-sectional view of the system of FIG. 5. Conductive ring 602 may be actuated horizontally and vertically as shown by the arrows to minimize gap g and make the ring 602 coplanar with the upper surface of wafer 403. Electric potential distribution is more uniform than in the comparative embodiment of FIGS. 3-4. By closing the gap, most of the distortion 609b is shifted away from an outer portion of wafer 603. However, when the inner contour of conductive ring 602 does not perfectly match edge of wafer 403, gap g cannot be completely closed. For example, wafer 603 is shown with a chamfered edge that prevents ring 602 from abutting the wafer perfectly. This causes a residual distortion 609a in electric potential distribution 609 that cannot be corrected by the system of FIGS. 5-6. Other physical conditions may create such distortion besides a chamfered wafer edge. For example, an alignment notch or flat may cause a residual gap between conductive ring 602 and wafer 603. A misalignment, damage, warping or manufacturing imperfection of conductive ring 602 or wafer 603 may also cause a residual gap.

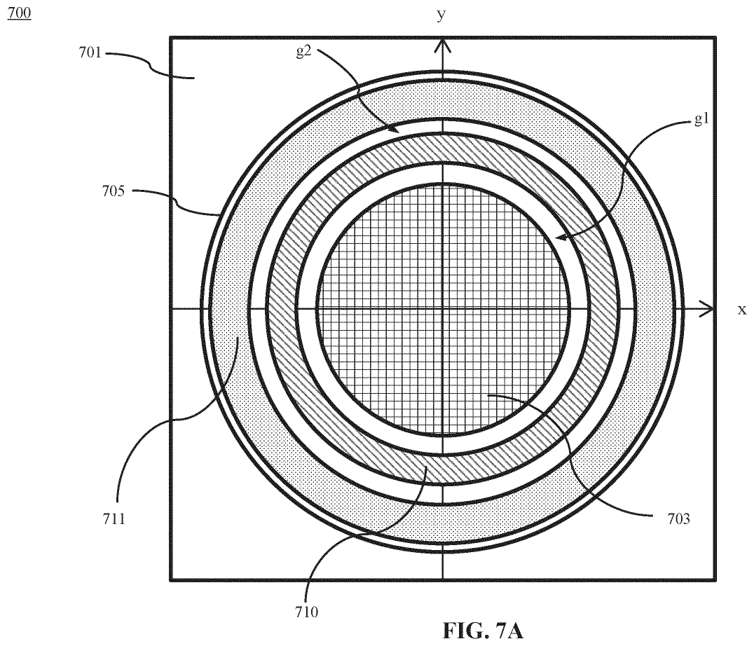

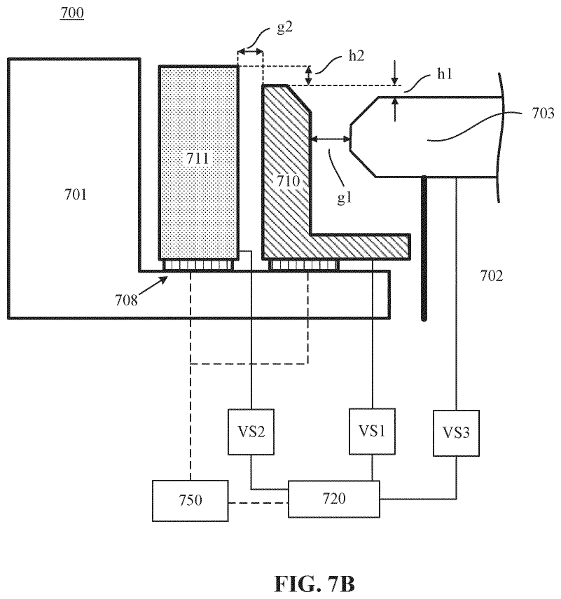

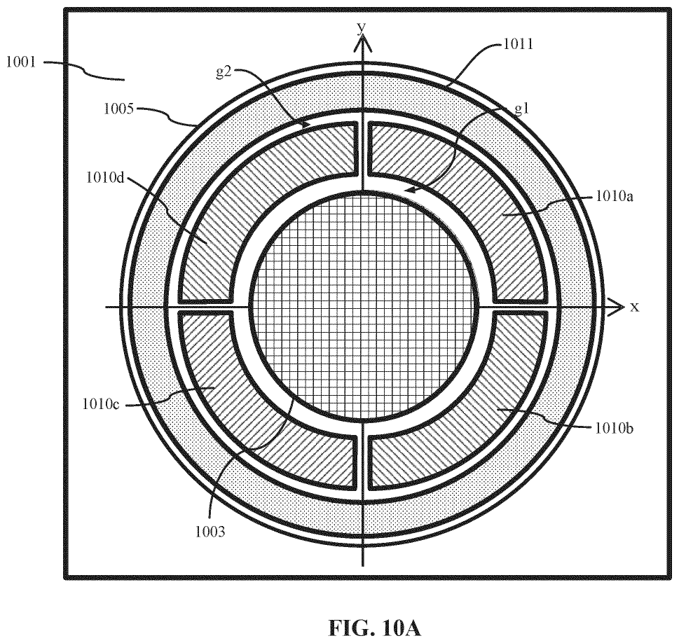

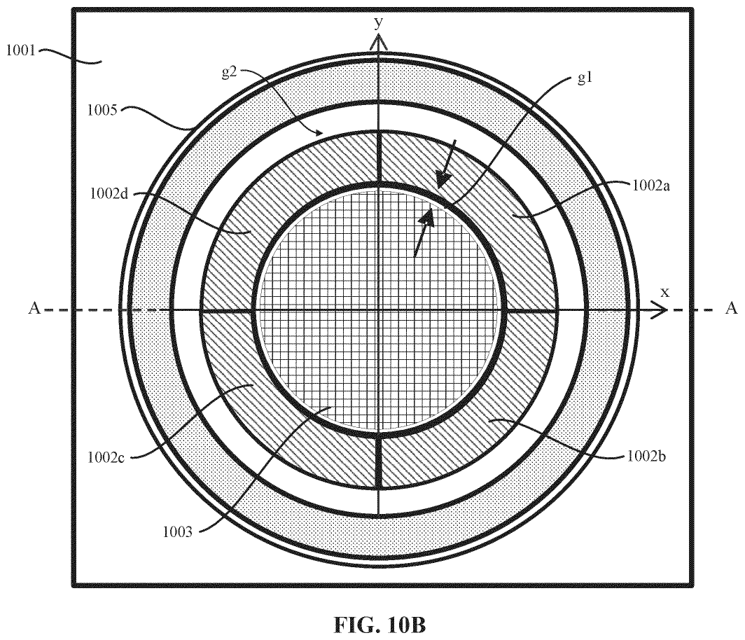

FIG. 7A illustrates a multi-ring system 700 according to some embodiments of the present disclosure. The multi-ring system comprises a plurality of substantially concentric conductive rings. In some embodiments the multi-ring system includes a first conductive ring 710 (“inner ring”) surrounding wafer 703 and a second conductive ring 711 (“outer ring”) surrounding inner ring 710. Wafer 703 is held on a holding portion 702 (not shown in FIG. 7A) of wafer holder 701. An inner diameter at a portion of inner ring 710 may be larger than an outer diameter of wafer 703 as illustrated by gap g1. An inner diameter at a portion of outer ring 711 may be larger than an outer diameter of inner ring 710 as illustrated by gap g2. In some embodiments, more than two conductive rings are provided. For example, there may be a middle ring located between inner ring 710 and outer ring 711. Inner ring 710 or outer ring 711 may comprise a plurality of conductive ring segments as further discussed below with respect to FIGS. 10A-B. The conductive rings may be formed of a conductive material, such as a metal. For example, the material may be a non-magnetic metallic material such as, e.g., Titanium, Aluminum etc. Alternatively, the conductive ring may be formed of a conductive coating of such material on a non-conductive structure.

FIG. 7B illustrates a cross-sectional view of the system of FIG. 7A. according to some embodiments of the present disclosure. First and second voltage supplies VS1/VS2 may be connected to the conductive material of inner ring 710 and outer ring 711, respectively. Third voltage supply VS3 may be connected to wafer 703. First, second and third voltage supplies VS1-VS3 may each provide independent voltages to inner ring 710, outer ring 711, and wafer 703, respectively, under control of a voltage controller 720. Voltage controller 720 may be coupled with a charged particle beam apparatus (e.g., EBI system 100). For example, voltage controller 720 may be controller 109 in FIG. 2. When applied to the inner ring 710, outer ring 711, and wafer 703, each of the first, second and third voltages produces an associated first, second, and third electric potential distribution respectively. For instance, the third voltage supply VS3 may be controlled so as to produce a third electric potential distribution at the surface of wafer 703. The third electric potential distribution may be substantially uniform and non-distorted over a majority of the wafer surface. But as discussed above, the third electric potential distribution can exhibit distortion at the wafer outer portion, which results in a distorted e-field. In some embodiments of the present disclosure, the first and second voltages from voltage supplies VS1 and VS2 may be chosen so that a superposition of the first and second electric potential distributions compensates the third electric potential distribution. In this way, the total superposition of all three electric potential distributions results in a combined electric potential distribution that extends uniformly across the outer portion and outward over the wafer edge. Several parameters may be optimized in order to achieve this result, including the magnitude and sign of the first and second voltages, as well as the relative gap spacings and heights of first and second conductive rings 710/711 to wafer 703.

Inner ring 710 or outer ring 711 may be fixed in place. Alternatively, inner ring 710 or outer ring 720 may be moveable in the horizontal or vertical directions by actuators 708 under the control of actuation controller 750. Actuation controller 750 may be coupled with a charged particle beam apparatus (e.g., EBI system 100). For example, actuation controller 750 may be controller 109 in FIG. 2. Actuation controller 750 may be voltage controller 720, or may be coupled with voltage controller 720 as seen in FIG. 7B. Configuring the conductive rings as fixed elements can provide a more robust and simpler design, whereas configuring the conductive rings as moveable elements makes the system more versatile. For example, providing moveable rings can allow greater freedom to make quick adjustments for different SEM settings. Further, moveable ring segments can help to avoid damage during wafer exchange as discussed above. In some embodiments, both inner ring 710 and outer ring 711 are in a fixed position and are non-segmented. In some embodiments, outer ring 711 is fixed and non-segmented while inner ring 710 is segmented and moveable to allow loading and unloading of wafer 703. In some embodiments, both inner ring 710 and outer ring 711 are moveable or have a moveable segment. As further discussed below, the multi-ring system does not require a conductive ring to be in contact with the edge of wafer 703, but instead allows it to be separated by a gap. This provides additional degrees of design freedom, and many variants are possible.

As seen in FIG. 7B, the location of inner ring 710 and outer ring 711 may be optimized in both the radial and height dimensions to achieve appropriate relative heights and gap distances. In some embodiments, height and gap distances may range from, e.g., 0.1-3 mm. In FIG. 7B, there is a first gap g1 between inner ring 710 and wafer 703, and a second gap g2 between outer ring 711 and inner ring 710. Also, because the upper surfaces of the rings do not need to be coplanar with wafer 703 or with each other in the multi-ring system, the optimizing may include height differences between elements. For example, there may be a first height difference h1 between the upper surfaces of wafer 703 and inner ring 710. There may be a second height difference h2 between the upper surfaces of outer ring 711 and inner ring 710. First height difference h1 may be greater than, or less than, second height difference h2. First and second height differences h1/h2 may be positive or negative in the radially outward direction. For example, a height change that increases in the radially outward direction from a wafer may be considered a positive height difference. A height change that decreases in the radially outward direction from a wafer may be considered a negative height difference. Because the magnitudes of the first and second electric potentials vary with distance from the first and second conductive rings 710 and 711, the heights and gap distances may be optimized to achieve very effective compensation at the outer portion of wafer 703 without impacting more radially inward regions of the third electric potential distribution. Here the “optimizing” of ring locations may refer to, e.g., active adjustment via actuators, appropriate design of a fixed arrangement, or offline manual adjustment.

The conductive rings may be arranged in ways other than what is shown in FIG. 7B. For example, while the upper surfaces of inner ring 710 and outer ring 711 are both shown higher than an upper surface of wafer 703, this is not necessarily the case. In some embodiments, an upper surface of inner ring 710 or outer ring 711 may be located substantially at or above a lower surface of wafer 703, or substantially at or above an upper surface of holding portion 702. Further, a portion of inner ring 710 is located underneath wafer 703 in FIG. 7B. However, this is not necessarily so. In some embodiments of the present disclosure, the innermost portion of inner ring 710 is located radially outward of the edge of wafer 703. In some embodiments, inner ring 710 may comprise a horizontally extending portion and a vertically extending portion as seen in FIG. 7B, wherein some part of the vertically extending portion is located radially inward of the edge of wafer 703. In some embodiments, inner ring 710 may comprise only a substantially vertically extending portion located radially inward of the edge of wafer 703. In some embodiments, the conductive rings have other cross-sectional shapes, such as square, circular, elliptical or more complex shapes.

In embodiments comprising a moveable conductive ring (or ring segment), the movement range may include the full possible range disclosed above or only a portion of the disclosed range. For example, some embodiments may include a moveable ring having a vertical movement range extending from, e.g., several mm above an upper surface of a wafer to, e.g., about halfway between an upper and lower surface of the wafer.

In addition to optimizing a spatial arrangement of the inner and outer rings 710/711, the magnitude and sign of the first and second voltages may be chosen to compensate the e-field on the wafer outer portion e-field.

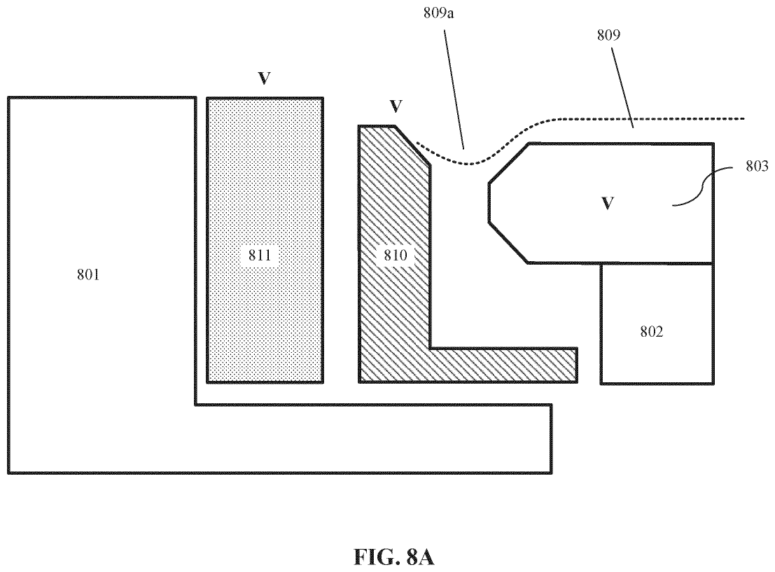

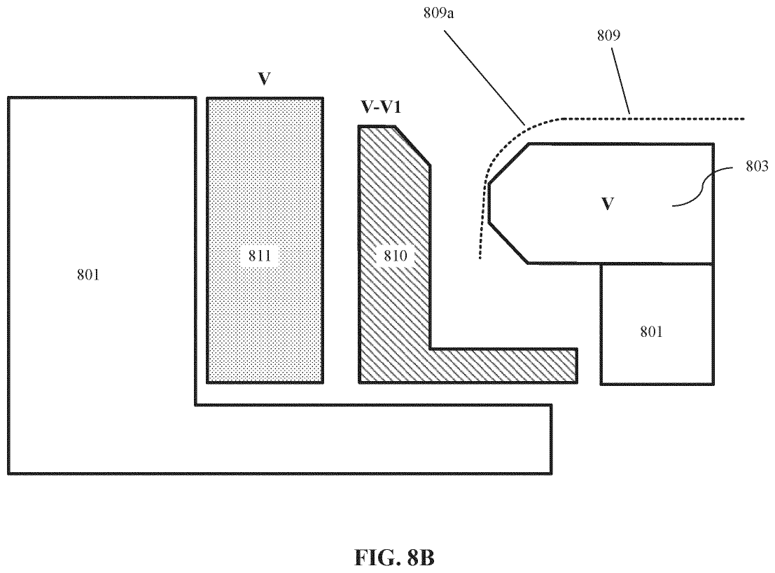

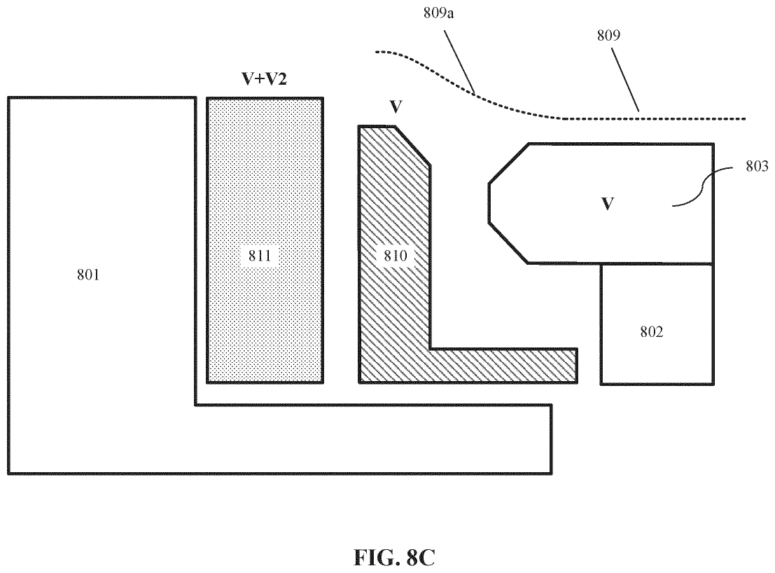

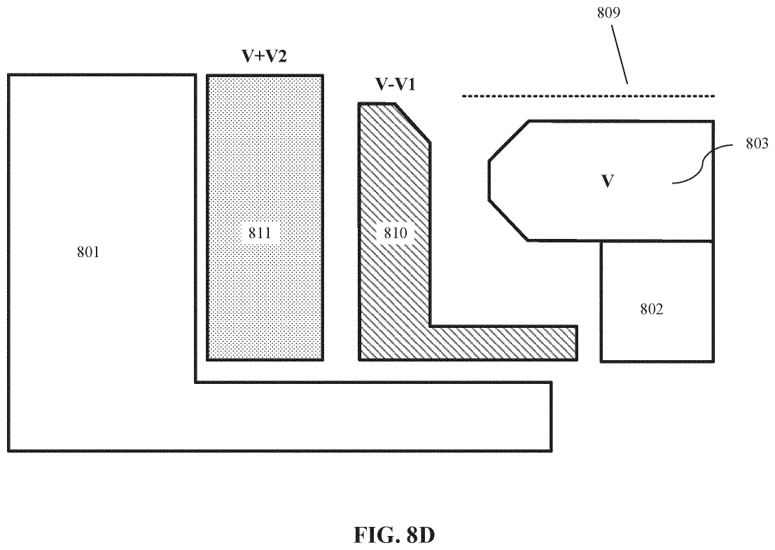

FIGS. 8A-D illustrate possible voltage supply arrangements according to some embodiments of the present disclosure. In FIG. 8A, a third voltage V is applied to wafer 803 by third voltage supply VS3 (not shown). Additionally, first and second voltage supplies VS1-VS2 (not shown) apply the same third voltage V to inner ring 810 and outer ring 811 respectively. The combined electric potential distribution 809 does not have an ideal flat form at the outer portion of wafer 803.

In the comparative embodiment of FIG. 8B, wafer 803 and outer ring 811 are still maintained at the same voltage V. However, between wafer 803 and outer ring 811, inner ring 810 is maintained at a first voltage (V−V1) that is less than V because the first voltage (V−V1) includes a first compensating voltage component (−V1). Stated another way, first voltage (V−V1) is equal to the third voltage V plus a first compensating delta value (−V1). Under this configuration, a distortion 809a in combined electric potential distribution 809 can be seen at an outer portion of wafer 803.

FIG. 8C illustrates another possible arrangement according to a comparative embodiment. Here, inner ring 810 is maintained at a same voltage V as wafer 803. Outer ring 811 is maintained at a second voltage (V+V2) higher than V because the second voltage (V+V2) includes a second compensating voltage component V2. Stated another way, second voltage (V+V2) is equal to the third voltage V plus a second compensating delta value V2. In this case, the distortion 809a at the outer portion of wafer 803 is similar, but opposite, to the distortion at FIGS. 8A-B.

FIG. 8D illustrates another possible arrangement 800 consistent with embodiments of the present disclosure. Here, both the inner ring 810 and outer ring 811 are held at different voltage values from each other, as well as from the value V applied to wafer 803. For example, a lower first compensating voltage (V−V1) may be applied to inner ring 810, and a higher second compensating voltage (V+V2) may be applied to outer ring 811. The delta values applied to inner and outer rings 810/811 may have an opposite sign. The superposition of first and second electric potential distributions generated by the inner and outer rings 810/811 very effectively compensates the outer portion distortion of the third electric potential distribution to produce a combined electric potential distribution 809 with high uniformity across a wafer outer portion.

The embodiments of FIG. 8A-C disclose arrangements in which one conductive ring is maintained at a same voltage as the wafer, and illustrate possible distortions associated with such an arrangement. However, it should be understood that these distortion examples are meant as illustrative aids to other embodiments of the present disclosure, such as FIG. 8D. They are not meant to imply that an electric potential distribution cannot be compensated using a voltage value equal to that of the wafer. As discussed above, the state of the combined electric potential distribution at the wafer outer portion is a function of many factors. For example, in addition to voltage values of the conductive rings, a gap spacing or height can be chosen so as to produce a desired electric potential at a desired point. In some embodiments of the present disclosure, the heights, gaps and voltages may be arranged such that a uniform combined electric potential distribution is achieved while an inner, outer, or other conductive ring is maintained at the same voltage as the wafer.

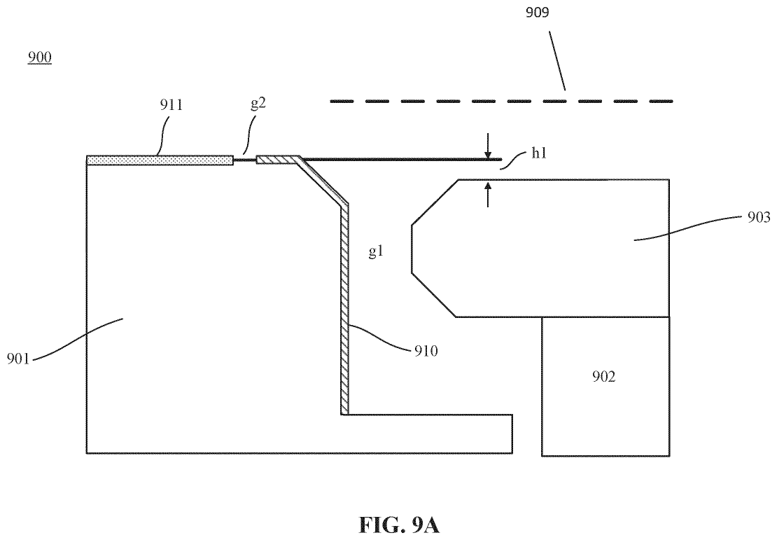

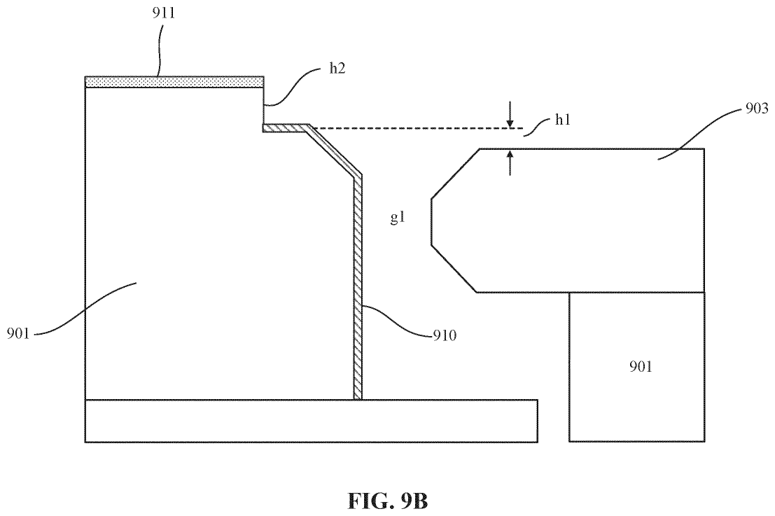

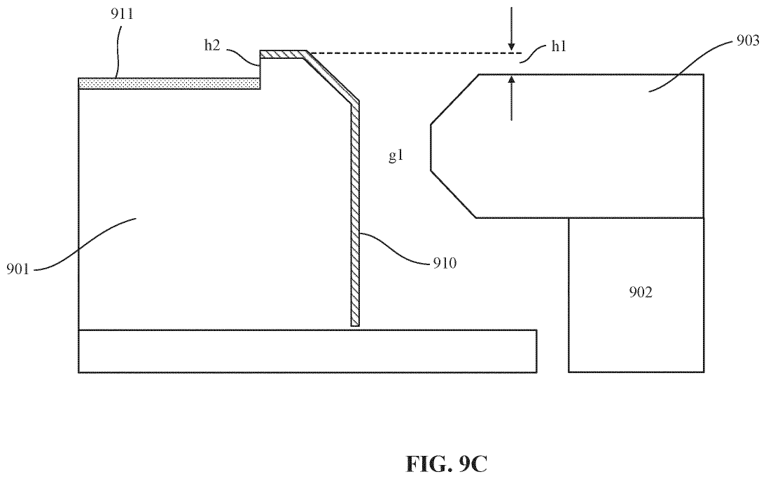

FIGS. 9A-C illustrate multi-ring systems according to some embodiments of the present

disclosure. Conductive rings 910 and 911 are formed as conductive coatings on a non-conductive surface. For example, the coatings may be non-magnetic metallic materials, e.g., Titanium, Aluminum etc., formed on a mirror block of wafer holder 901. Coatings 910 and 911 operate as electrodes in a similar manner to rings 710 and 711 of FIGS. 7A-B or rings 810 and 811 of FIGS. 8A-D.

Coatings 910 and 911 may be connected to independently controlled voltage supplies VS1/VS2

(not shown), similar to the embodiment of FIG. 7B. Voltage supplies VS1/VS2 may apply voltages as discussed with respect to FIGS. 7A-B or FIGS. 8A-D. For instance, a voltage applied to coating 910 by voltage supply VS1 may be greater than, less than, or equal to a voltage applied to coating 911 by voltage supply VS2.

Coatings 910 and 911 may be formed with various heights and gap distances as needed to produce a desired compensation at an outer portion of wafer 903. The surface on which the coatings are formed (such as a mirror block of the wafer holder) may likewise have a surface profile corresponding to the desired heights and gap distances. For instance, in FIG. 9A, height difference h2 (not shown) between inner ring 910 and outer ring 911 is zero. In FIG. 9B, height difference h2 is positive while gap g2 (not shown) is zero. In FIG. 9C, height difference h2 is negative while gap g2 is zero. It will be appreciated that other configurations are possible, so long as the coatings are arranged to allow a desired compensation at the wafer outer portion. For example, when height h2 is nonzero, gap g2 could be negative, i.e., there may be overlap in the radial direction between inner and outer rings 910 and 911.

Furthermore, the coatings need not be located on mirror block of the wafer holder. A single conductive ring may comprise a non-conductive ring structure on which both inner ring 910 and outer ring 911 are deposited as conductive films. The non-conductive ring structure may be fixed or movable. and segmented or continuous as discussed above with respect to the previous embodiments.

In general, ideal values for voltages, heights, gap spacings and other parameters depend upon the particular apparatus setup, imaging conditions, and sample under inspection (or other processing), as well as upon each other. Suitable values may be determined through modeling or experiment and stored, e.g., in a software lookup table for use during a charged particle beam process such as SEM inspection of a wafer. Embodiments of the present disclosure allow for rapid adjustment of spatial or electrical parameters to account for changes to process conditions based on prior information. Additionally, process data may be fed back to the system for real-time correction during a current or subsequent process. For example, information from an image acquirer of a SEM inspection system may be used to characterize distortion of the e-field at a wafer outer portion. The information may include, e.g., a characteristic type of image distortion that corresponds to an expected type of e-field distortion at the wafer outer portion. The image may also be compared to a reference feature layout at the wafer outer portion in order to identify distortion. Corrections may be fed back based on the process data.

FIGS. 10A and 10B illustrate a segmented multi-ring system according to some embodiments of the present disclosure. Providing segmented conductive rings may allow a wafer to be loaded and unloaded more easily with less risk of a collision. The following description refers to an embodiment in which only inner ring 1010 is segmented or moveable. However, it should be understood that outer ring 1011 may also be segmented or moveable in an analogous manner. Alternatively or additionally, the segmented or moveable arrangement may be applied to embodiments in which both conductive rings are formed on a single structure, such as the embodiments of FIGS. 9A-C.

FIG. 10A is an illustration of a top view of an example system during wafer loading, according to some embodiments of the present disclosure. Shown in FIG. 10A are a wafer holder 1001, a wafer 1003, conductive outer ring 1011, and four segments of a conductive inner ring 1010, denoted 1010a-d. Wafer 1003 is held on a holding portion (not shown) of a wafer holder. A gap g2 exists between an inner side of outer ring 1011 and an outer side of conductive ring segments 1010a-d. Similarly, a gap g1 exists between and inner side of conductive ring segments 1010a-d and an edge of wafer 1003.

In some embodiments, during the loading of wafer 1003, wafer holder 1001 is kept stationary. The four segments 1010a-d of conductive ring 1010 are then moved radially outward towards outer ring 1011, increasing the size of gap g1. This helps avoid collision with the edge of wafer 1003. The segments are not moved so far outward as to cause a collision with outer ring 1011. Outer ring 1011 may also be segmented and moveable so that segments of the outer ring move radially outward towards an inner side 1005 of wafer holder 1001 during or before movement of the inner ring segments 1010a-d. In this way, gap g2 is maintained at a safe size during the radially outward movement. The conductive ring segments can be moved individually, or all at once or in any combination. After wafer 1003 is loaded, the four segments 1010a-d of the conductive ring can be moved radially inwards towards wafer 1003 to bring gap g1 back to an operational size.

A top view of the disclosed system after the wafer 1003 is loaded is shown in FIG. 10B. The conductive ring segments have been moved closer to wafer 1003, and gap g1 is once again optimized for e-field compensation.

In some embodiments, conductive ring segments 1010a-d are designed to have the same inner radius of curvature as the radius of the wafer 1003, as a result of which the gap g1 may be uniform around the wafer when the radially oriented surfaces of segments 1010a-d are substantially in contact with each other to complete the conductive ring 1010. Moreover, the gap g2 between outer ring 1011 and inner ring 1010 is larger in FIG. 10B than it is in FIG. 10A.

Furthermore, outer ring 1011 and inner ring 1010 may be supplied with voltages as discussed above, thereby providing a continuous extension of the wafer e-field over a wafer outer portion including the wafer edge.

While FIGS. 10A and 10B show a conductive ring having four segments, it is appreciated that any number of segments can be used. For example, the minimal number of segments can be two. Moreover, it is appreciated that some of the segments can be in a fixed position. For example, it is appreciated that segment 1010d can be in a fixed position with respect to the radial direction, while the other segments (i.e., segments 1010a, 1010b, and 1010c) can be moved radially inward and outwards.

The process of moving the conductive ring 1010 as described above may be referred to as a conductive ring adjustment process. In some embodiments, in order to save time required for the conductive ring adjustment process, there can be two sets of wafer holders, a first wafer holder for performing the e-beam inspection and a second wafer holder for wafer loading and conductive ring adjustment process to be performed in parallel. That is, a wafer in the first wafer holder can undergo the e-beam inspection while a wafer in the second wafer holder can undergo wafer loading and the conductive ring adjustment process. It is appreciated that after the wafer in the first wafer holder has undergone the e-beam inspection, the conductive ring can be adjusted to remove the wafer and the first wafer holder can be moved to the wafer loading position for loading of a next wafer. In the same time frame, the second wafer holder, after undergoing the conductive ring adjustment process, can be positioned for inspection. Further details of the system of FIGS. 10A-B can be found in U.S. Application No. 63/274,918, the entirety of which is incorporated herein by reference.

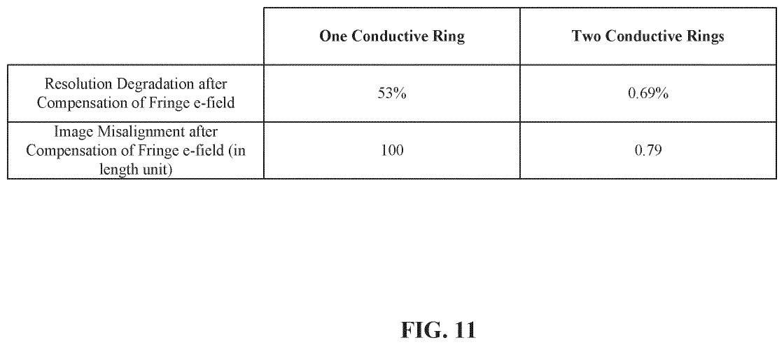

FIG. 11 illustrates example experimental results comparing a single conductive ring (single mirror block electrode coating) of a comparative embodiment with a multi-ring system (two mirror block electrode coatings) according to embodiments of the present disclosure. In addition to image misalignment from beam shift, resolution due to a change in spot size is considered. For the single mirror block coating, resolution is degraded by 53% and image misalignment is given at a normalized value of 100 in arbitrary units of length. Under a two-mirror block coating according to embodiments of the present disclosure, opposite bias voltages can be applied to yield a precise compensation of edge field distortion. Image misalignment due to beam deflection due to edge field distortion is reduced to 0.79, and resolution is nearly identical between the wafer edge and center.

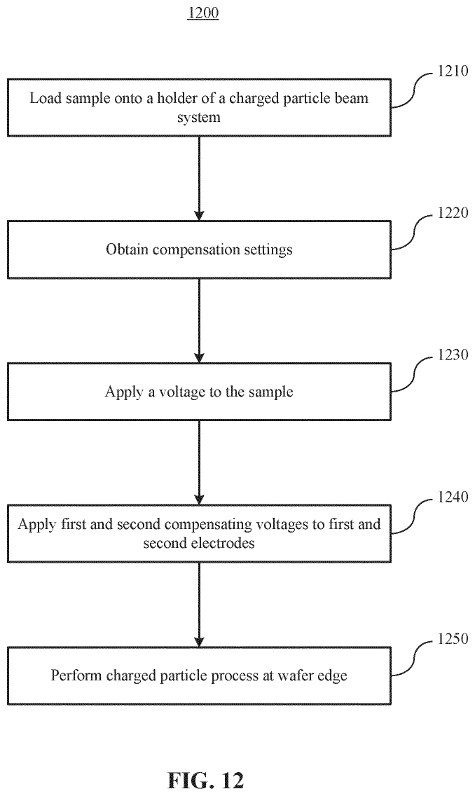

FIG. 12 illustrates a flowchart of an example method 1200 for compensating edge field distortion in a charged particle beam process according to embodiments of the present disclosure. Method 1200 may be performed by a charged particle beam system (e.g., EBI system 100 of FIG. 1). The charged particle beam system may include an edge field compensation system according to embodiments of the present disclosure. For example, the process may utilize the systems of FIG. 7A-B. FIGS. 8A-D, or FIGS. 9A-C.

At step 1210, a sample is loaded onto a holder in the charged particle beam system. For example, the sample may be a wafer (e.g., such as wafers 703/803/903/1003).

At step 1220, compensation settings are acquired for the process. Compensation settings may include particular values or ranges for any of the parameters associated with the edge field compensation process. Compensation settings may include voltage values applied to an inner conductive ring, an outer conductive ring, a further conductive ring, or wafer. Compensation settings may include positional settings, such as a height or gap distance of a conductive ring relative to another conductive ring or the sample. The values or ranges for the compensation settings may be based on information about, e.g., apparatus settings, imaging conditions, sample conditions, detection data, experiment, computer modeling, current or prior charged particle processes. The information may be stored in a software lookup table or other information database.

At step 1230, a voltage is applied to the sample. The voltage may be responsible for creating a substantially uniform electric potential distribution over the upper surface of the sample. The potential distribution from the voltage may include a distortion at the sample outer portion, which is compensated by first and second voltages discussed below.

At step 1240, first and second compensating voltages are applied to first and second electrodes. The first and second electrodes may be, e.g., conductive rings 710/711, 810/811 or coatings 910/911, or 1010/1011. The first electrode may be an inner electrode that substantially encircles the sample. The second electrode may be an outer ring that substantially encircles the inner ring. The method may include applying further voltages to further electrodes. The first or second electrodes may be continuous or segmented. The first or second electrodes may be fixed or moveable. The first or second electrodes may comprise a metal or other conductive material. The first or second electrodes may be conductive coatings formed on a non-conductive surface.

The first compensating voltage may be different from the voltage or the second compensating voltage. The second compensating voltage may be different from the first compensating voltage or the voltage. For example, the first compensating voltage may be less than the voltage, and the voltage may be less than the second compensating voltage. Stated another way, the first or second compensating voltages may be equal to the voltage plus first or second compensating delta values. The compensating delta values may be positive or negative.

At step 1250, the charged particle beam system performs a charged particle process at an edge of the sample. For example, the charged particle beam system may be an EBI system 100 of FIG. 1. The charged particle beam process may be a SEM inspection at an outer portion of a wafer. Due to the compensating effect of the first and second voltages on the first and second conductive rings, a combined electric potential distribution extends substantially uniformly over an outer portion and past the wafer edge. This results in an outer portion e-field having little or no distortion. Using the above method, a charged particle beam process may be performed at an outer portion of a sample with fine resolution and low beam deflection due to edge effects.

It should be apparent that not all steps of the method 1200 need to be performed in the order presented, and some steps may be performed simultaneously. For example, step 1220 of obtaining compensation settings may be performed prior to step 1210 of loading a sample into the charged particle beam system. Step 1240 of applying first and second voltages may be performed prior to, after, or simultaneously with, step 1230 of applying a third voltage. For instance, it may be advantageous to apply the voltage simultaneously with the first and second compensating voltages in order to reduce the risk of arcing.

It should also be noted that the apparatuses and systems as described in association with FIGS. 1-12 are not limited to be used in wafer inspection. Instead, they can be used for any system or apparatus that includes a high-voltage part and an adjustable mechanical assembly, and has a demand for uniform voltage distribution or elimination of any distortion near the wafer edge. For example, such system or apparatus may include, but not limited to, a SEM, a transmission electron microscopy (TEM), an electron beam lithography tool, or an X-ray machine.

A non-transitory computer readable medium may be provided that stores instructions for a

processor (for example, processor of controller 109 of FIG. 1) to carry out image processing, data processing, database management, graphical display, operations of a charged particle beam apparatus, or another imaging device, performing wafer inspection, moving conductive ring radially outward to create a space to place a wafer on a stage, placing wafer on the stage, moving the conductive ring radially inward until the conductive ring is within a predetermined distance from a wafer edge, sensing voltages of the conductive ring and the wafer, sensing the positions of the conductive ring and the wager, adjusting the voltage of the conductive ring to be equal to the voltage of the wafer to create a substantially uniform e-field, adjusting the position of the conductive ring to be equal to the position of the wafer to make the top surfaces of both co-planar, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments may further be described using the following clauses:
1. A system for reducing e-field distortion near an outer portion of a wafer comprising:
a wafer holder comprising a holding portion configured to hold a wafer, the wafer having a first outer diameter;
a first conductive electrode configured to surround the wafer, the first conductive electrode having a second inner diameter and a third outer diameter, the second inner diameter being larger than the first outer diameter;
a second conductive electrode configured to encircle the first conductive electrode, the second conductive ring having a fourth inner diameter larger than the second inner diameter;
a first, second, and third voltage supply, the first voltage supply being connected to the first conductive electrode, the second voltage supply being connected to the second conductive electrode, the third voltage supply being connected to the wafer; and
a controller configured to control each of the first, second, and third voltage supplies to operate at a first, second, and third voltage respectively; wherein
the first, second and third voltages are selected to reduce distortion of an e-field at the outer portion of the wafer, and
the first, second and third voltages are different from each other.
2. The system of clause 1, wherein the second voltage is lower than the first voltage.
3. The system of clause 1, wherein the second voltage is higher than the first voltage.
4. The system of clause 1, wherein the third voltage is higher than the first voltage.
5. The system of clause 1, wherein the third voltage is lower than the first voltage.
6. The system of clause 1, wherein the first conductive electrode or the second conductive electrode has a fixed position.
7. The system of clause 1, wherein the first conductive electrode and the second conductive electrode have a fixed position.
8. The system of clause 1, wherein the first conductive electrode or the second conductive electrode is moveable in a first direction.
9. The system of clause 8, wherein the first direction is a radial direction or a height direction.
10. The system of clause 1, further comprising a third conductive electrode positioned between the first conductive electrode and the second conductive electrode.
11. The system of clause 1, further comprising a first gap between the second inner diameter and the first outer diameter.
12. The system of clause 1, further comprising a second gap between the third outer diameter and the fourth inner diameter.
13. The system of clause 1, wherein
the first conductive electrode comprises a first upper surface;
the second conductive electrode comprises a second upper surface; and
the first upper surface or the second upper surface is configured to be not coplanar with an upper surface of the wafer.
14. The system of clause 13, wherein the first upper surface or the second upper surface is configured to be substantially level with, or higher than, an upper surface of the wafer.
15. The system of clause 13, wherein the first upper surface or the second upper surface is configured to be substantially level with, or higher than, a lower surface of the wafer.
16. The system of clause 13, further comprising a first height difference between the first upper surface and an upper surface of the wafer.
17. The system of clause 16, wherein the first height difference is a positive height difference.
18. The system of clause 16, wherein the first height difference is a negative height difference.
19. The system of clause 13, further comprising a second height difference between the first upper surface and the second upper surface.
20. The system of clause 19, wherein the second height difference is a positive height difference.
21. The system of clause 19, wherein the second height difference is a negative height difference.
22. The system of clause 1, wherein the first conductive electrode or the second conductive electrode is a conductive ring.
23. The system of clause 22, wherein the first conductive electrode or the second conductive electrode is a conductive coating on a non-conductive material.
24. The system of clause 23, wherein the non-conductive material is portion of the wafer holder surrounding the holding portion.
25. The system of clause 1, wherein the first conductive electrode or the second conductive electrode is divided into segments comprising a first segment and a second segment.
26. The system of clause 25, wherein the first segment is moveable with respect to the second segment.
27. A system for reducing e-field distortion near an outer portion of a wafer comprising:
a wafer holder comprising a holding portion configured to hold a wafer, the wafer having a first outer diameter;
a first conductive electrode configured to surround the wafer, the first conductive electrode having a second inner diameter and a third outer diameter, the second inner diameter being larger than the first outer diameter;
a second conductive electrode configured to encircle the first conductive electrode, the second conductive ring having a fourth inner diameter larger than the second inner diameter; and
a first, second, and third voltage supply, the first voltage supply being connected to the first conductive electrode, the second voltage supply being connected to the second conductive electrode, the third voltage supply being connected to the wafer; and
a controller configured to control each of the first, second, and third voltage supplies to operate at a first, second, and third voltage respectively; wherein
the first, second and third voltages are selected to reduce distortion of an e-field at the outer portion of the wafer.
28. The system of clause 27, wherein the controller is configured to control each of the first, second, and third voltage supplies so that the each of the first, second, and third voltages are different from each other.
29. The system of clause 27, wherein the second voltage is lower than the first voltage.
30. The system of clause 27, wherein the second voltage is higher than the first voltage.
31. The system of clause 27, wherein the third voltage is higher than the first voltage.
32. The system of clause 27, wherein the third voltage is lower than the first voltage.
33. The system of clause 27, wherein the first conductive electrode or the second conductive electrode has a fixed position.
34. The system of clause 27, wherein the first conductive electrode and the second conductive electrode have a fixed position.
35. The system of clause 27, wherein the first conductive electrode or the second conductive electrode is moveable in a first direction.
36. The system of clause 35, wherein the first direction is a radial direction or a height direction.
37. The system of clause 27, further comprising a third conductive electrode positioned between the first conductive electrode and the second conductive electrode.
38. The system of clause 27, further comprising a first gap between the second inner diameter and the first outer diameter.
39. The system of clause 27, further comprising a second gap between the third outer diameter and the fourth inner diameter.
40. The system of clause 27, wherein
the first conductive electrode comprises a first upper surface;
the second conductive electrode comprises a second upper surface; and
the first upper surface or the second upper surface is configured to not be coplanar with an upper surface of the wafer.
41. The system of clause 40, wherein the first upper surface or the second upper surface is configured to be substantially level with, or higher than, an upper surface of the wafer.
42. The system of clause 40, wherein the first upper surface or the second upper surface is configured to be substantially level with, or higher than, a lower surface of the wafer.
43. The system of clause 40, further comprising a first height difference between the first upper surface and an upper surface of the wafer.
44. The system of clause 43, wherein the first height difference is a positive height difference.
45. The system of clause 43, wherein the first height difference is a negative height difference.
46. The system of clause 40, further comprising a second height difference between the first upper surface and the second upper surface.
47. The system of clause 46, wherein the second height difference is a positive height difference.
48. The system of clause 46, wherein the second height difference is a negative height difference.
49. The system of clause 27, wherein the first conductive electrode or the second conductive electrode is a conductive ring.
50. The system of clause 49, wherein the first conductive electrode or the second conductive electrode is a conductive coating on a non-conductive material.
51. The system of clause 50, wherein the non-conductive material is portion of the wafer holder surrounding the holding portion.
52. The system of clause 27, wherein the first conductive electrode or the second conductive electrode is divided into segments comprising a first segment and a second segment.
53. The system of clause 52, wherein the first segment is moveable with respect to the second segment.
54. A non-transitory computer-readable medium storing a set of instructions that are executable by at least one processor of a device to cause the device to perform a method comprising:
loading a wafer onto a wafer holder comprising a holding portion, the wafer having a first outer diameter;
applying a first voltage to a first conductive electrode encircling the holding portion, the first conductive electrode having a second inner diameter and a third outer diameter, the second inner diameter being larger than the first outer diameter;
applying a second voltage to a second conductive electrode encircling the first conductive electrode, the second conductive electrode having a fourth inner diameter larger than the second inner diameter; and
applying a third voltage to the wafer; wherein
the first, second and third voltages are selected to reduce distortion of an e-field at the outer portion of the wafer, and
the first, second and third voltages are different from each other.
55. The non-transitory computer-readable medium of clause 54, wherein the second voltage is lower than the first voltage.
56. The non-transitory computer-readable medium of clause 54, wherein the second voltage is higher than the first voltage.
57. The non-transitory computer-readable medium of clause 54, wherein the third voltage is higher than the first voltage.
58. The non-transitory computer-readable medium of clause 54, wherein the third voltage is lower than the first voltage.
59. The non-transitory computer-readable medium of clause 54, wherein the first conductive electrode or the second conductive electrode has a fixed position.
60. The non-transitory computer-readable medium of clause 54, wherein the first conductive electrode and the second conductive electrode have a fixed position.
61. The non-transitory computer-readable medium of clause 54, wherein the set of instructions that are executable by the at least one processor of the device cause the device to further perform:
moving the first conductive electrode or the second conductive electrode in a first direction.
62. The non-transitory computer-readable medium of clause 61, wherein the first direction is a radial direction or a height direction.
63. The non-transitory computer-readable medium of clause 54, wherein the set of instructions that are executable by the at least one processor of the device cause the device to further perform:
applying a fourth voltage to a third conductive electrode positioned between the first conductive electrode and the second conductive electrode.
64. The non-transitory computer-readable medium of clause 54, wherein a first gap exists between the second inner diameter and the first outer diameter.
65. The non-transitory computer-readable medium of clause 54, wherein a second gap exists between the third outer diameter and the fourth inner diameter.
66. The non-transitory computer-readable medium of clause 54, wherein
the first conductive electrode comprises a first upper surface;
the second conductive electrode comprises a second upper surface; and
the first upper surface or the second upper surface is not coplanar with an upper surface of the wafer.
67. The non-transitory computer-readable medium of clause 66, wherein the first upper surface or the second upper surface is substantially level with, or higher than, an upper surface of the wafer.
68. The non-transitory computer-readable medium of clause 66, wherein the first upper surface or the second upper surface is configured to be substantially level with, or higher than, a lower surface of the wafer.
69. The non-transitory computer-readable medium of clause 66, wherein a first height difference exists between the first upper surface and an upper surface of the wafer.
70. The non-transitory computer-readable medium of clause 69, wherein the first height difference is a positive height difference.
71. The non-transitory computer-readable medium of clause 69, wherein the first height difference is a negative height difference.
72. The non-transitory computer-readable medium of clause 66, wherein a second height difference exists between the first upper surface and the second upper surface.
73. The non-transitory computer-readable medium of clause 72, wherein the second height difference is a positive height difference.
74. The non-transitory computer-readable medium of clause 72, wherein the second height difference is a negative height difference.
75. The non-transitory computer-readable medium of clause 54, wherein the first conductive electrode or the second conductive electrode is a conductive ring.
76. The non-transitory computer-readable medium of clause 54, wherein the first conductive electrode or the second conductive electrode is a conductive coating on a non-conductive material.
77. The non-transitory computer-readable medium of clause 76, wherein the non-conductive material is portion of the wafer holder surrounding the holding portion.
78. The non-transitory computer-readable medium of clause 54, wherein the first conductive electrode or the second conductive electrode is divided into segments comprising a first segment and a second segment.
79. The non-transitory computer-readable medium of clause 78, wherein the set of instructions that are executable by the at least one processor of the device to cause the device to further perform:
moving the first segment with respect to the second segment.
80. A method, comprising:
loading a wafer onto a wafer holder comprising a holding portion, the wafer having a first outer diameter;
applying a first voltage to a first conductive electrode encircling the holding portion, the first conductive electrode having a second inner diameter and a third outer diameter, the second inner diameter being larger than the first outer diameter;
applying a second voltage to a second conductive electrode encircling the first conductive electrode, the second conductive electrode having a fourth inner diameter larger than the second inner diameter; and
applying a third voltage to the wafer;
wherein the first, second and third voltages are different from each other.
81. The method of clause 80, further comprising:
selecting the first, second and third voltages to reduce distortion of an e-field at an outer portion of the wafer.
82. The method of clause 80, wherein the second voltage is lower than the first voltage.
83. The method of clause 80, wherein the second voltage is higher than the first voltage.
84. The method of clause 80, wherein the third voltage is higher than the first voltage.
85. The method of clause 80, wherein the third voltage is lower than the first voltage.
86. The method of clause 80, wherein the first conductive electrode or the second conductive electrode has a fixed position.
87. The method of clause 80, wherein the first conductive electrode and the second conductive electrode have a fixed position.
88. The method of clause 80, further comprising:
moving the first conductive electrode or the second conductive electrode in a first direction.
89. The method of clause 88, wherein the first direction is a radial direction or a height direction.
90. The method of clause 80, further comprising:
applying a fourth voltage to a third conductive electrode positioned between the first conductive electrode and the second conductive electrode.
91. The method of clause 80, wherein a first gap exists between the second inner diameter and the first outer diameter.
92. The method of clause 80, wherein a second gap exists between the third outer diameter and the fourth inner diameter.
93. The method of clause 80, wherein
the first conductive electrode comprises a first upper surface;
the second conductive electrode comprises a second upper surface; and
the first upper surface or the second upper surface is not coplanar with an upper surface of the wafer.
94. The method of clause 93, wherein the first upper surface or the second upper surface is substantially level with, or higher than, an upper surface of the wafer.
95. The method of clause 93, wherein the first upper surface or the second upper surface is configured to be substantially level with, or higher than, a lower surface of the wafer.
96. The method of clause 93, wherein a first height difference exists between the first upper surface and an upper surface of the wafer.
97. The method of clause 96, wherein the first height difference is a positive height difference.
98. The method of clause 96, wherein the first height difference is a negative height difference.
99. The method of clause 93, wherein a second height difference exists between the first upper surface and the second upper surface.
100. The method of clause 99, wherein the second height difference is a positive height difference.
101. The method of clause 99, wherein the second height difference is a negative height difference.
102. The method of clause 80, wherein the first conductive electrode or the second conductive electrode is a conductive ring.
103. The method of clause 80, wherein the first conductive electrode or the second conductive electrode is a conductive coating on a non-conductive material.
104. The method of clause 103, wherein the non-conductive material is portion of the wafer holder surrounding the holding portion.
105. The method of clause 80, wherein the first conductive electrode or the second conductive electrode is divided into segments comprising a first segment and a second segment.
106. The method of clause 105, wherein the set of instructions that are executable by the at least one processor of the device cause the device to further perform:
moving the first segment with respect to the second segment.
107. A non-transitory computer-readable medium storing a set of instructions that are executable by at least one processor of a device to cause the device to perform a method comprising:
loading a wafer onto a wafer holder comprising a holding portion, the wafer having a first outer diameter;
applying a first voltage to a first conductive electrode encircling the holding portion, the first conductive electrode having a second inner diameter and a third outer diameter, the second inner diameter being larger than the first outer diameter;
applying a second voltage to a second conductive electrode encircling the first conductive electrode, the second conductive electrode having a fourth inner diameter larger than the second inner diameter; and
applying a third voltage to the wafer; wherein
the first, second and third voltages are different from each other.
108. The non-transitory computer-readable medium of clause 107, wherein the set of instructions that are executable to cause the device to further perform:
selecting the first, second and third voltages to reduce distortion of an e-field at an outer portion of the wafer.
109. The non-transitory computer-readable medium of clause 107, wherein the second voltage is lower than the first voltage.
110. The non-transitory computer-readable medium of clause 107, wherein the second voltage is higher than the first voltage.
111. The non-transitory computer-readable medium of clause 107, wherein the third voltage is higher than the first voltage.
112. The non-transitory computer-readable medium of clause 107, wherein the third voltage is lower than the first voltage.
113. The non-transitory computer-readable medium of clause 107, wherein the first conductive electrode or the second conductive electrode has a fixed position.
114. The non-transitory computer-readable medium of clause 107, wherein the first conductive electrode and the second conductive electrode have a fixed position.
115. The non-transitory computer-readable medium of clause 107, wherein the set of instructions that are executable by the at least one processor of the device to cause the device to further perform: moving the first conductive electrode or the second conductive electrode in a first direction.
116. The non-transitory computer-readable medium of clause 115, wherein the first direction is a radial direction or a height direction.
117. The non-transitory computer-readable medium of clause 107, wherein the set of instructions that are executable by the at least one processor of the device to cause the device to further perform:
applying a fourth voltage to a third conductive electrode positioned between the first conductive electrode and the second conductive electrode.
118. The non-transitory computer-readable medium of clause 107, wherein a first gap exists between the second inner diameter and the first outer diameter.
119. The non-transitory computer-readable medium of clause 107, wherein a second gap exists between the third outer diameter and the fourth inner diameter.
120. The non-transitory computer-readable medium of clause 107, wherein
the first conductive electrode comprises a first upper surface;
the second conductive electrode comprises a second upper surface; and
the first upper surface or the second upper surface is not coplanar with an upper surface of the wafer.
121. The non-transitory computer-readable medium of clause 120, wherein the first upper surface or the second upper surface is substantially level with, or higher than, an upper surface of the wafer.
122. The non-transitory computer-readable medium of clause 120, wherein the first upper surface or the second upper surface is configured to be substantially level with, or higher than, a lower surface of the wafer.
123. The non-transitory computer-readable medium of clause 120, wherein a first height difference exists between the first upper surface and an upper surface of the wafer.
124. The non-transitory computer-readable medium of clause 123, wherein the first height difference is a positive height difference.
125. The non-transitory computer-readable medium of clause 123, wherein the first height difference is a negative height difference.
126. The non-transitory computer-readable medium of clause 120, wherein a second height difference exists between the first upper surface and the second upper surface.
127. The non-transitory computer-readable medium of clause 126, wherein the second height difference is a positive height difference.
128. The non-transitory computer-readable medium of clause 126, wherein the second height difference is a negative height difference.
129. The non-transitory computer-readable medium of clause 107, wherein the first conductive electrode or the second conductive electrode is a conductive ring.
130. The non-transitory computer-readable medium of clause 107, wherein the first conductive electrode or the second conductive electrode is a conductive coating on a non-conductive material.
131. The non-transitory computer-readable medium of clause 130, wherein the non-conductive material is portion of the wafer holder surrounding the holding portion.
132. The non-transitory computer-readable medium of clause 107, wherein the first conductive electrode or the second conductive electrode is divided into segments comprising a first segment and a second segment.
133. The non-transitory computer-readable medium of clause 133, wherein the set of instructions that are executable by the at least one processor of the device to cause the device to further perform: moving the first segment with respect to the second segment.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A system for reducing e-field distortion near an outer portion of a wafer comprising:
a wafer holder comprising a holding portion configured to hold a wafer, the wafer having a first outer diameter;
a first conductive electrode configured to surround the wafer, the first conductive electrode having a second inner diameter and a third outer diameter, the second inner diameter being larger than the first outer diameter;
a second conductive electrode configured to encircle the first conductive electrode, the second conductive ring having a fourth inner diameter larger than the second inner diameter;
a first, second, and third voltage supply, the first voltage supply being connected to the first conductive electrode, the second voltage supply being connected to the second conductive electrode, the third voltage supply being connected to the wafer; and
a controller configured to control each of the first, second, and third voltage supplies to operate at a first, second, and third voltage respectively; wherein
the first, second and third voltages are selected to reduce distortion of an e-field at the outer portion of the wafer, and
the first, second and third voltages are different from each other.

2. The system of claim 1, wherein the second voltage is higher than the first voltage.

3. The system of claim 1, wherein the third voltage is higher than the first voltage.

4. The system of claim 1, wherein the first conductive electrode or the second conductive electrode has a fixed position.

5. The system of claim 1, wherein the first conductive electrode or the second conductive electrode is moveable in a first direction.

6. The system of claim 5, wherein the first direction is a radial direction or a height direction.

7. The system of claim 1, wherein
the first conductive electrode comprises a first upper surface;
the second conductive electrode comprises a second upper surface; and
the first upper surface or the second upper surface is configured to be not coplanar with an upper surface of the wafer.

8. The system of claim 7, wherein the first upper surface or the second upper surface is configured to be substantially level with, or higher than, an upper surface of the wafer.

9. The system of claim 7, further comprising a first height difference between the first upper surface and an upper surface of the wafer.

10. The system of claim 1, wherein the first conductive electrode or the second conductive electrode is a conductive ring.

11. The system of claim 10, wherein the first conductive electrode or the second conductive electrode is a conductive coating on a non-conductive material.

12. The system of claim 11, wherein the non-conductive material is portion of the wafer holder surrounding the holding portion.

13. The system of claim 1, wherein the first conductive electrode or the second conductive electrode is divided into segments comprising a first segment and a second segment.

14. The system of claim 13, wherein the first segment is moveable with respect to the second segment.

15. A non-transitory computer-readable medium storing a set of instructions that are executable by at least one processor of a device to cause the device to perform a method comprising:
loading a wafer onto a wafer holder comprising a holding portion, the wafer having a first outer diameter;
applying a first voltage to a first conductive electrode encircling the holding portion, the first conductive electrode having a second inner diameter and a third outer diameter, the second inner diameter being larger than the first outer diameter;
applying a second voltage to a second conductive electrode encircling the first conductive electrode, the second conductive electrode having a fourth inner diameter larger than the second inner diameter; and
applying a third voltage to the wafer; wherein
the first, second and third voltages are selected to reduce distortion of an e-field at the outer portion of the wafer, and
the first, second and third voltages are different from each other.

16. A system for reducing e-field distortion near an outer portion of a wafer comprising:
a wafer holder comprising a holding portion configured to hold a wafer, the wafer having a first outer diameter;
a first conductive electrode configured to surround the wafer, the first conductive electrode having a second inner diameter and a third outer diameter, the second inner diameter being larger than the first outer diameter;
a second conductive electrode configured to encircle the first conductive electrode, the second conductive ring having a fourth inner diameter larger than the second inner diameter; and
a first, second, and third voltage supply, the first voltage supply being connected to the first conductive electrode, the second voltage supply being connected to the second conductive electrode, the third voltage supply being connected to the wafer; and
a controller configured to control each of the first, second, and third voltage supplies to operate at a first, second, and third voltage respectively; wherein
the first, second and third voltages are selected to reduce distortion of an e-field at the outer portion of the wafer.

17. The system of claim 16, wherein the controller is configured to control each of the first, second, and third voltage supplies so that the each of the first, second, and third voltages are different from each other.

18. The system of claim 16, wherein the second voltage is lower than the first voltage.

19. The system of claim 16, wherein the second voltage is higher than the first voltage.

20. The system of claim 16, wherein the third voltage is higher than the first voltage.
